(19) United States
(12) Patent Application Publication
(10) Pub. No.: US 2026/0006807 A1
(43) Pub. Date: Jan. 1, 2026

(54) SEMICONDUCTOR STRUCTURE AND MANUFACTURING METHOD THEREFOR

(71) Applicant: CXMT Corporation, Hefei City (CN)

(72) Inventors: Yuefeng CAO, Hefei City (CN); Chiyuan MA, Hefei City (CN); Dejian TANG, Hefei City (CN); Kun WANG, Hefei City (CN); Shiyuan JIA, Hefei City (CN)

(73) Assignee: CXMT Corporation, Hefei City (CN)

(21) Appl. No.: 18/966,696

(22) Filed: Dec. 3, 2024

Related U.S. Application Data
(63) Continuation of application No. PCT/CN2024/126303, filed on Oct. 22, 2024.

(30) Foreign Application Priority Data
Jun. 27, 2024 (CN) 202410853846.3

(51) Int. Cl. H10D 1/68; H10D 1/00

(52) U.S. Cl. CPC H10D 1/716; H10D 1/045

(57) ABSTRACT

Disclosed are a semiconductor structure and a manufacturing method therefor. The manufacturing method includes the following: a stack is formed on a base; multiple bottom electrodes are formed in the stack, each of the bottom electrodes including a body portion in the stack and an extension portion protruding from the stack; the extension portion is etched, so that a horizontal width of the extension portion is less than a horizontal width of the body portion; a dielectric layer and a conductive film layer are successively formed on the stack, the extension portion being covered by the dielectric layer and the conductive film layer; the conductive film layer is etched to expose the stack and form multiple conductive support layers; the stack is etched to expose the body portion; a dielectric layer is formed on the body portion; and a top electrode is formed on the dielectric layer.

### CROSS REFERENCE TO RELATED APPLICATIONS

This application is a continuation of International Patent Application No. PCT/CN2024/126303 filed on Oct. 22, 2024, which claims priority to Chinese Patent Application No. 202410853846.3 filed on Jun. 27, 2024. The disclosures of the above-referenced applications are hereby incorporated by reference in their entirety.

### BACKGROUND

Dynamic random access memories (DRAMs) are semiconductor memories widely applied to multi-computer systems. As one of necessary structures in a DRAM, capacitors provide functions such as voltage regulation and filtering in circuits, and are extensively applied to integrated circuits.

With the advancement of fabrication processes, the size of capacitor holes and the spacing in between are becoming increasingly small, leading to increased difficulty in forming capacitor structures.

### SUMMARY

Embodiments of the present disclosure relate to the field of semiconductor technologies, and in particular, to a semiconductor structure and a manufacturing method therefor.

According to a first aspect of the embodiments of the present disclosure, a manufacturing method for a semiconductor structure is provided, including:
a stack is formed on a base;
multiple bottom electrodes are formed in the stack, each of the bottom electrodes including a body portion in the stack and an extension portion protruding from the stack;
the extension portion is etched, so that the horizontal width of the extension portion is less than the horizontal width of the body portion;
a dielectric layer and a conductive film layer are successively formed on the stack, the extension portion being covered by the dielectric layer and the conductive film layer;
the conductive film layer is etched to expose the stack and form multiple conductive support layers;
the stack is etched to expose the body portion;
a dielectric layer is formed on the body portion; and
a top electrode is formed on the dielectric layer.

According to a second aspect of embodiments of the present disclosure, a semiconductor structure is provided, including:
a base;
multiple bottom electrodes located on the base, each of the bottom electrodes including a body portion and an extension portion, and the horizontal width of the extension portion being less than the horizontal width of the body portion;
an intermediate support layer, located in a middle region of the body portion;
a conductive support layer, located on the extension portion, a dielectric layer being present between the conductive support layer and the extension portion; and
a conductive pillar, located on the conductive support layer.

### BRIEF DESCRIPTION OF THE DRAWINGS

FIG. 1 is a schematic diagram of lateral etching of a top support layer in an etching process according to an example embodiment;

FIG. 2 is a schematic diagram of bottom-electrode material bridging according to an example embodiment;

FIG. 3 is a schematic diagram of a residual first sacrificial layer according to an example embodiment;

FIG. 4 is a flowchart of a manufacturing method for a semiconductor structure according to an example embodiment;

FIG. 5 is a schematic diagram of forming a stack according to an example embodiment;

FIG. 6 is a schematic diagram of forming a capacitor hole according to an example embodiment;

FIG. 7 is a schematic top view of FIG. 6 according to an example embodiment;

FIG. 8 is another schematic diagram of forming a capacitor hole according to an example embodiment;

FIG. 9 is a schematic diagram of filling a bottom-electrode material according to an example embodiment;

FIG. 10 is a schematic diagram of forming bottom electrodes according to an example embodiment;

FIG. 11 is a schematic top view of FIG. 10 according to an example embodiment;

FIG. 12 is another schematic diagram of forming bottom electrodes according to an example embodiment;

FIG. 13 is a schematic diagram of etched extension portions according to an example embodiment;

FIG. 14 is a schematic diagram of forming a conductive film layer according to an example embodiment;

FIG. 15 is an enlarged view of a dashed-line box in FIG. 14 according to an example embodiment;

FIG. 16 is a schematic diagram of forming conductive support layers according to an example embodiment;

FIG. 17 is a schematic diagram of forming a top electrode according to an example embodiment;

FIG. 18 is a schematic diagram of a position of a dielectric layer according to an example embodiment;

FIG. 19 is a schematic diagram of removing a top electrode on a surface according to an example embodiment;

FIG. 20 is a schematic diagram of forming a top electrode plate according to an example embodiment;

FIG. 21 is a schematic diagram of a semiconductor structure according to an example embodiment;

FIG. 22 is a schematic diagram of a second bottom electrode according to an example embodiment; and

FIG. 23 is a schematic diagram of an electronic device according to an example embodiment.

### DETAILED DESCRIPTION

The technical solutions of the present disclosure are further described below in detail with reference to the accompanying drawings and the embodiments. Although example implementations of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily indicate a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. Multiple sublayers may be included in the layer.

It should be noted that the technical solutions described in the embodiments of the present disclosure may be randomly combined when there is no conflict.

As shown in FIG. 1, in some embodiments, when pillar capacitor structures are formed, a bottom support layer 102, a first sacrificial layer 103, an intermediate support layer 104, a second sacrificial layer 105, a top dielectric layer 1051, and a mask layer 106 may be successively formed on a base 101. Then, the top dielectric layer 1051, the second sacrificial layer 105, the intermediate support layer 104, the first sacrificial layer 103, and the bottom support layer 102 are successively etched based on the mask layer 106 to form capacitor holes 107. In some embodiments, the material of the mask layer 106 is polysilicon, and the material of the top dielectric layer 1051 is silicon nitride. When the mask layer 106 is removed with an etching gas, and the capacitor holes 107 are formed, the etching gas has a high etching selectivity ratio for polysilicon over silicon nitride. In addition, when the etching gas carries out etching downward, the top dielectric layer 1051 is always etched by the etching gas, that is, the top dielectric layer 1051 is etched for a long time. Consequently, the top dielectric layer 1051 is subject to lateral etching to certain extent, forming grooves 1071 on the top dielectric layer 1051.

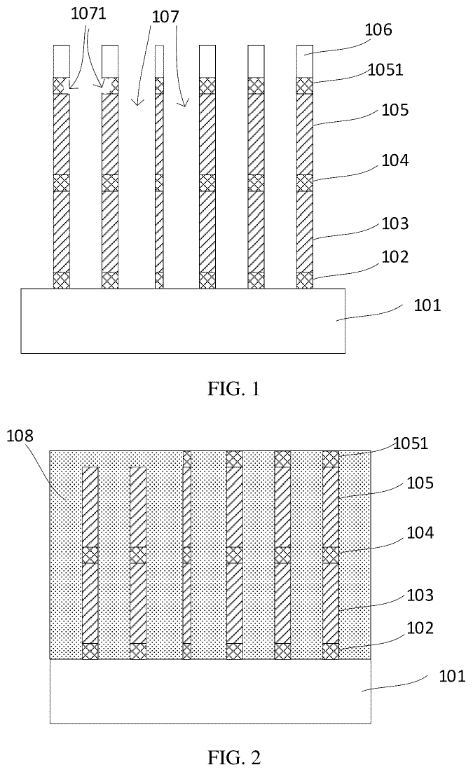

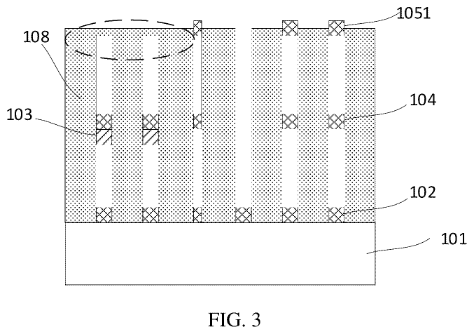

As shown in FIG. 2 and FIG. 3, in some embodiments, grooves 1071 are formed in some regions in the top dielectric layers 1051. In a worse case, all these regions in the top dielectric layers 1051 are consumed by the etching gas. Therefore, when the capacitor holes 107 are filled with a bottom-electrode material 108, in the regions with the top dielectric layer 1051 fully consumed, the bottom-electrode material 108 is interconnected (as in a dashed-line box in FIG. 3). That is, subsequently, bottom electrodes are interconnected, causing capacitors to be short-circuited. In addition, because the bottom-electrode material 108 is bridged, no hole can be provided on this part of the bottom-electrode material 108. As a result, the first sacrificial layer 103 below the bottom-electrode material 108 cannot be fully removed, that is, a part of the first sacrificial layer 103 still remains. Consequently, this region cannot be filled with a dielectric layer and a top electrode, damaging integrity of a capacitor structure and reducing a capacitor capacity.

As shown in FIG. 1, in some embodiments, the researcher also finds that, as a depth-to-width ratio of the capacitor holes keeps increasing, a spacing between some capacitor holes 107 is less than that between other capacitor holes 107 in a process of forming the capacitor holes 107. This is not conducive to subsequent filling of the dielectric layer and the top electrode, affecting integrity of the capacitor structure.

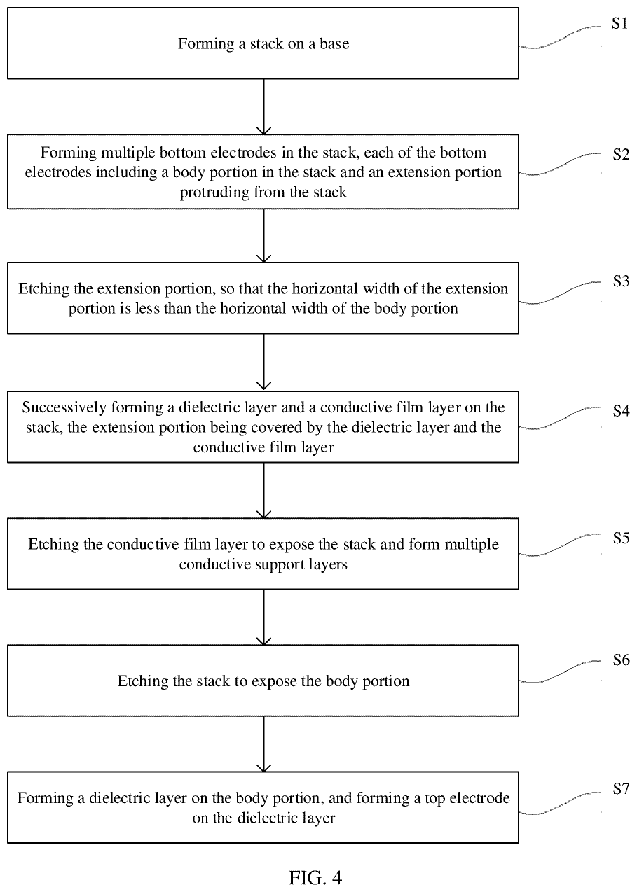

As shown in FIG. 4, to alleviate the foregoing problem, embodiments of the present disclosure provide a manufacturing method for a semiconductor structure. The method may be configured to manufacture a pillar capacitor, thereby facilitating filling of a dielectric layer and a top electrode, and simplifying a manufacturing process of a capacitor structure. The manufacturing method includes the following steps:
S1: a stack is formed on a base;
S2: multiple bottom electrodes are formed in the stack, each of the bottom electrodes including a body portion in the stack and an extension portion protruding from the stack;
S3: the extension portion is etched, so that the horizontal width of the extension portion is less than the horizontal width of the body portion;
S4: a dielectric layer and a conductive film layer are successively formed on the stack, the extension portion being covered by the dielectric layer and the conductive film layer; S5: the conductive film layer is etched to expose the stack and form multiple conductive support layers;
S6: the stack is etched to expose the body portion; and
S7: a dielectric layer is formed on the body portion, and a top electrode is formed on the dielectric layer.

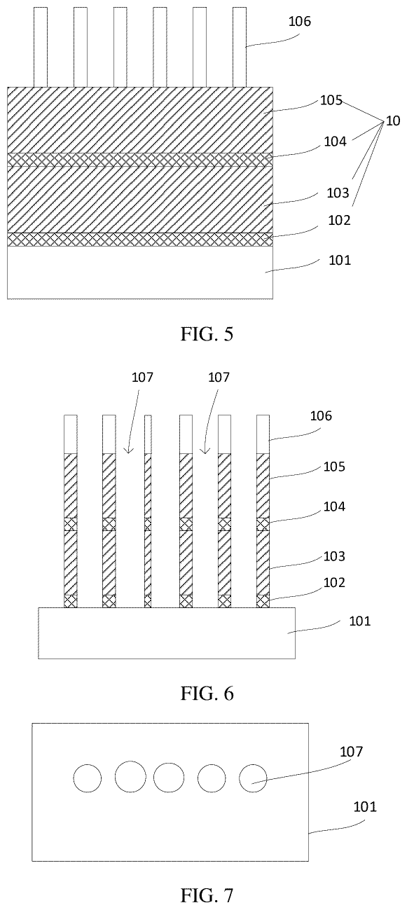

As shown in FIG. 5, in the step of S1, a base 101 is first provided, and then a bottom support layer 102, a first sacrificial layer 103, an intermediate support layer 104, and a second sacrificial layer 105 are successively formed on the base 101, that is, a stack 10 is formed on the base 101. The base 10 may include silicon, germanium, silicon germanium, or a III-V compound semiconductor (e.g., GaP or GaAs). In some embodiments, the base 10 may be a silicon on insulator substrate or a germanium on insulator substrate. The base 101 may include structures such as a word line and a bit line.

As shown in FIG. 5, the stack 10 may be formed by a physical vapor deposition process, a chemical vapor deposition process, or an atomic layer deposition process. In the embodiments of the present disclosure, the materials of the bottom support layer 102 and the intermediate support layer 104 may be the same, and the materials of the first sacrificial layer 103 and the second sacrificial layer 105 may be the same. In a subsequent etching process, parts of the bottom support layer 102 and the intermediate support layer 104 may still be retained, which can support the bottom electrodes. The first sacrificial layer 103 and the second sacrificial layer 105 are fully removed in a subsequent process. The first sacrificial layer 103 and the second sacrificial layer 105 may be soft materials such as phosphoro silicate glass (PSG), boro-phospho-silicate glass (BPSG), or fluoro silicate glass (FSG). The bottom support layer 102 and the intermediate support layer 104 may be nitrides, such as silicon nitrides, silicon carbonitrides, silicon oxynitrides, or silicon boronitrides.

As shown in FIG. 5, in the embodiments of the present disclosure, the thickness of the first sacrificial layer 103 is substantially the same as the thickness of the second sacrificial layer 105, the thickness of the bottom support layer 102 is substantially the same as the thickness of the intermediate support layer 104, and the thickness of the first sacrificial layer 103 is greater than the thickness of the bottom support layer 102. The first sacrificial layer 103 has a larger thickness, and subsequently both the first sacrificial layer 103 and the second sacrificial layer 105 are removed, thereby increasing a capacitor capacity. The thickness of the first sacrificial layer 103 may be 300 nm to 1000 nm, e.g., 400 nm, 500 nm, 600 nm, 700 nm, 800 nm, or 900 nm. The thickness of the bottom support layer 102 may be 10 nm to 80 nm, e.g., 20 nm, 30 nm, 40 nm, 50 nm, 60 nm, or 70 nm.

As shown in FIG. 5, after the stack 10 is formed, a mask layer 106 is directly formed on the stack 10, that is, the mask layer 106 is directly formed on the second sacrificial layer 105. The mask layer 106 is then patterned to expose the second sacrificial layer 105. In the embodiments of the present disclosure, the material of the mask layer 106 may be polysilicon. When the stack 10 is etched based on the mask layer 106, as the material of the second sacrificial layer 105 is silicon oxide, an etching gas has a small etching selectivity ratio for polysilicon over silicon oxide, and therefore, no lateral etching is performed on silicon oxide. In the embodiments of the present disclosure, the mask layer 106 is directly formed on the second sacrificial layer 105, that is, the stack 10 includes no top dielectric layer, thereby preventing subsequent occurrence of a bottom-electrode material bridging problem.

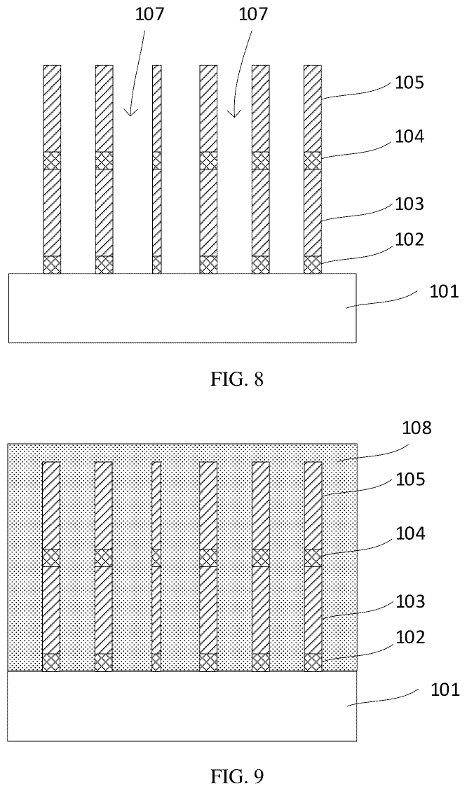

As shown in FIG. 6 to FIG. 8, in the step of S2, the stack 10 is etched based on the mask layer 106, that is, the second sacrificial layer 105, the intermediate support layer 104, the first sacrificial layer 103, and the bottom support layer 102 are etched based on the mask layer 106. In other words, capacitor holes 107 are formed in the stack 10. In some embodiments, the stack 10 may be etched by dry etching, that is, parts of all of the second sacrificial layer 105, the intermediate support layer 104, the first sacrificial layer 103, and the bottom support layer 102 are removed by dry etching. When etching is performed, a large quantity of capacitor holes 107 are formed. Because the capacitor holes 107 have a high depth-to-width ratio and an increasingly high density, some capacitor holes 107 have larger apertures, while some other capacitor holes 107 have smaller apertures during etching. For example, it may be seen from FIG. 7 that, starting from the left of FIG. 7, the first capacitor hole 107 has a smaller aperture, and the second and third capacitor holes 107 have larger apertures. Therefore, it can be seen that a spacing between the first capacitor hole 107 and the second capacitor hole 107 is larger, and a spacing between the second capacitor hole 107 and the third capacitor hole 107 is smaller. Consequently, in a subsequent process, it is difficult to form a dielectric layer and a top electrode between the second capacitor hole 107 and the third capacitor hole 107. The mask layer 106 is gradually consumed during forming of the capacitor holes 107. The mask layer 106 is fully consumed after the capacitor holes 107 are formed. In addition, because the intermediate support layer 104 is located in a middle region of the stack 10, when the capacitor holes 107 are formed, a time taken to etch the intermediate support layer 104 is reduced. Although the intermediate support layer 104 is subject to lateral etching, no bottom-electrode material bridging is caused, and not all of the intermediate support layer 104 is etched. Therefore, it can be ensured that the bottom electrodes are independent of each other and are not short-circuited.

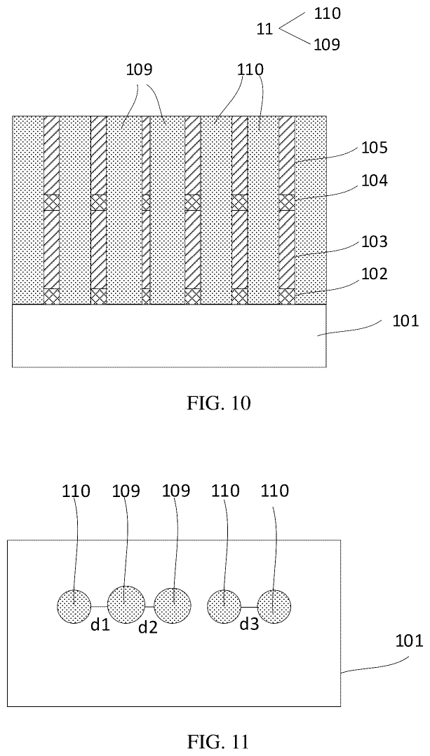

As shown in FIG. 9 and FIG. 10, in the step of S2, after the capacitor holes 107 are formed, the capacitor holes 107 are filled with a bottom-electrode material 108. In the embodiments of the present disclosure, the bottom-electrode material 108 may be filled in the capacitor holes 107 in a chemical vapor deposition manner, and the capacitor holes 107 can be fully filled with the bottom-electrode material 108. The bottom-electrode material 108 may be metal nitride or metal silicide, e.g., titanium nitride. Because the capacitor holes 107 are fully covered by the bottom-electrode material 108, a polishing process is performed on the bottom-electrode material 108, so that the bottom-electrode material 108 is flush with the second sacrificial layer 105, thereby forming mutually independent bottom electrodes. In addition, because the second sacrificial layer 105 is not subject to lateral etching, or rather a degree of lateral etching on the second sacrificial layer 105 is minimal, the top of the second sacrificial layer 105 is not etched, preventing bridging of the bottom-electrode material 108, and further avoiding a short-circuit problem of the bottom electrodes.

As shown in FIG. 10 and FIG. 11, in the embodiments of the present disclosure, bottom electrodes 11 may be classified into first bottom electrodes 109 and second bottom electrodes 110, that is, the bottom electrodes may include multiple first bottom electrodes 109 and multiple second bottom electrodes 110. The first bottom electrodes 109 and the second bottom electrodes 110 are all mutually independent, that is, these bottom electrodes are separated by the second sacrificial layer 105, the intermediate support layer 104, the first sacrificial layer 103, and the bottom support layer 102. It can be seen from FIG. 11 that a spacing d1 between one of the first bottom electrodes 109 and one of the second bottom electrodes 110 is greater than a spacing d2 between the first bottom electrodes 109. A spacing d3 between the second bottom electrodes 110 may be greater than the spacing d1 between the first bottom electrode 109 and the second bottom electrode 110, that is, the spacing between the first bottom electrodes 109 is the smallest. It may be seen from FIG. 10 that the horizontal width of the second sacrificial layer 105 between the first bottom electrodes 109 is the smallest.

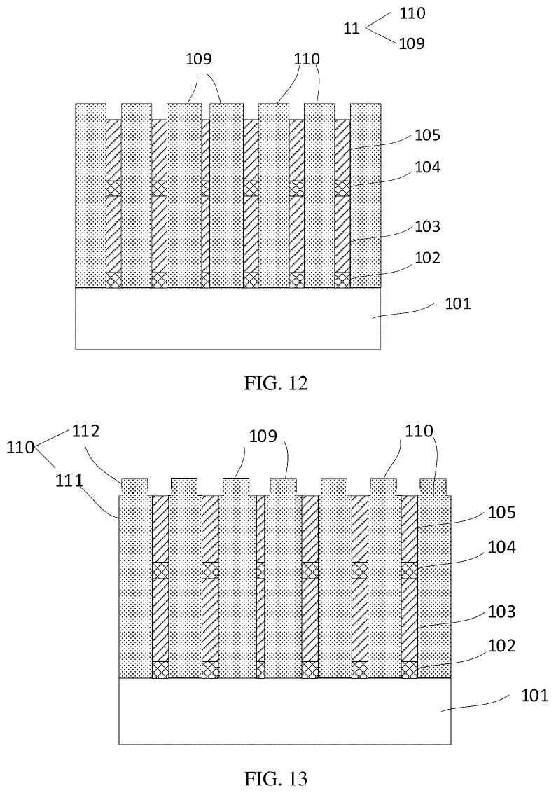

As shown in FIG. 12, in the step of S3, after the bottom electrodes 11 (the first bottom electrodes 109 and the second bottom electrodes 110) are formed, the second sacrificial layer 105 is dry etched, so that the height of the second sacrificial layer 105 is lower than that of the bottom electrodes. The embodiments of the present disclosure are described by taking the second bottom electrodes 110 as an example. After the second sacrificial layer 105 is etched, the second bottom electrodes 110 are made to protrude from the second sacrificial layer 105. That is, each of the second bottom electrodes 110 may include a body portion 111 and an extension portion 112. The body portion 111 may be located in the stack 10, and the extension portion 112 may protrude from the stack 10, that is, the extension portion 112 protrudes from the second sacrificial layer 105. In the embodiments of the present disclosure, the etched thickness of the second sacrificial layer 105 may be substantially the same as the thickness of the intermediate support layer 104, that is, the height of the extension portion 112 may be substantially the same as the thickness of the intermediate support layer 104. If the height of the extension portion 112 is excessively large, the height of the body portion 111 is reduced, possibly reducing a capacitor capacity. If the height of the extension portion 112 is excessively small, when a conductive support layer is subsequently formed on the extension portion 112, the height of a capacitor structure is increased, increasing a risk of capacitor collapse (bottom electrode collapse). Therefore, in the embodiments of the present disclosure, the height of the extension portion 112 may be substantially the same as the thickness of the intermediate support layer 104, thereby ensuring a capacitor capacity, and further preventing collapse of the capacitor structure.

As shown in FIG. 13, after the second bottom electrodes 110 are formed, the extension portion 112 of each of the second bottom electrodes 110 is etched, making the horizontal width of the extension portion 112 be less than the horizontal width of the body portion 111. As the horizontal width of the extension portion 112 is small, a spacing between the extension portions 112 is increased. In addition, because of the blocking effect of the second sacrificial layer 105, the etching gas does not affect the body portion 111, thereby ensuring integrity of the body portion 111. It should be noted that, for the structure of the first bottom electrodes 109, reference may be made to the structure of the second bottom electrodes 110.

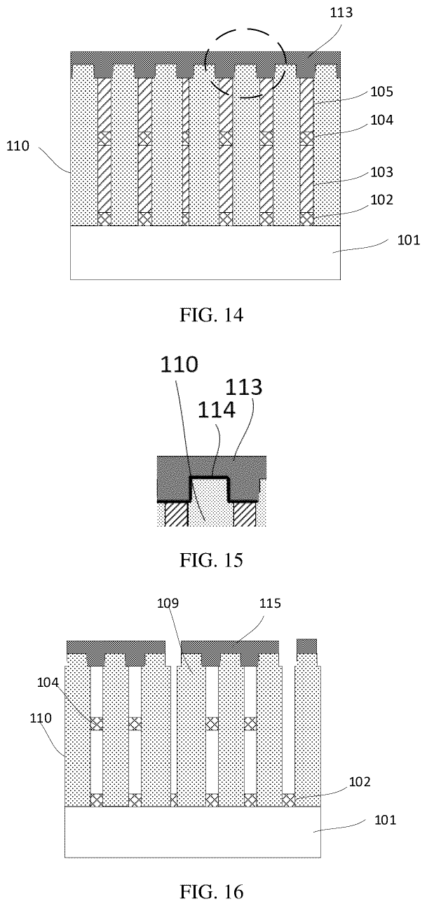

As shown in FIG. 14 and FIG. 15, in the step of S4, after the extension portion 112 is etched, a dielectric layer 114 and a conductive film layer 113 may be successively formed on the stack 10. A surface of the extension portion 112 and a surface of the second sacrificial layer 105 are covered by the dielectric layer 114. The dielectric layer 114 is covered by the conductive film layer 113. Moreover, a gap between the extension portions 112 may be fully filled with the conductive film layer 113, and the extension portion 112 is further covered by the conductive film layer 113. For example, the dielectric layer 114 and the conductive film layer 113 may be formed by a chemical vapor deposition process. The dielectric layer 114 may be a capacitor dielectric layer, and may be a high-K material, e.g., zirconium oxide, hafnium oxide, titanium zirconium oxide, ruthenium oxide, antimony oxide, or aluminium oxide. The conductive film layer 113 may be a silicon germanium layer or a metal tungsten layer. Because the dielectric layer 114 is present between the conductive film layer 113 and the extension portion 112, a capacitor structure is formed, thereby increasing a capacitor capacity.

As shown in FIG. 16, in the steps of S4 and S5, after the conductive film layer 113 is formed, the conductive film layer 113 and the dielectric layer 114 are etched, that is, the stack 10 is exposed, to be specific, the second sacrificial layer 105 is exposed. Meanwhile, multiple conductive support layers 115 may be further formed. When the conductive support layers 115 are formed, a part of the conductive film layer 113 between the extension portions 112 is first etched to expose the dielectric layer 114 on sidewalls of the extension portions 112, and then the dielectric layer 114 is etched to expose the sidewalls of the extension portions 112. It may be seen from FIG. 16 that each of the conductive support layers 115 may be located on the extension portion 112. Sidewalls of the conductive support layers 115 may be flush with the sidewalls of the extension portions 112, that is, the conductive support layers 115 are not located between the extension portions 112, that is, the spacing between the extension portions 112 is not reduced. After the second sacrificial layer 105 is exposed, a gap between the conductive support layers 115 may be utilized to remove the second sacrificial layer 105 and the first sacrificial layer 103 based on the gap through a wet etching solution, and a part of the intermediate support layer 104 may also be removed, thereby exposing the body portion 111.

As shown in FIG. 16, in the embodiments of the present disclosure, because the first bottom electrodes 109 and the second bottom electrodes 110 are mutually independent and are not interconnected, the second sacrificial layer 105 can be exposed when the conductive support layers 115 are formed. Therefore, when the second sacrificial layer 105 and the first sacrificial layer 103 are removed through the wet etching solution, it can be ensured that the second sacrificial layer 105 and the first sacrificial layer 103 are entirely removed, thereby effectively avoiding residuals of these sacrificial layers.

As shown in FIG. 16, in the embodiments of the present disclosure, because a gap between the first bottom electrodes 109 is relatively small, the second sacrificial layer 105 between the first bottom electrodes 109 is already exposed when the conductive support layers 115 are formed. Therefore, the wet etching chemical solution can remove the second sacrificial layer 105, the intermediate support layer 104, and the first sacrificial layer 103 between the first bottom electrodes 109. In addition, the intermediate support layer 104 directly below the conductive support layers 115 is not removed. Therefore, the intermediate support layer 104 may be located in middle regions of the first bottom electrodes 109, thereby supporting the first bottom electrodes 109. Certainly, the intermediate support layer 104 is also located in middle regions of the second bottom electrodes 110. The middle regions may be middle positions of the first bottom electrodes 109 or the second bottom electrodes 110.

As shown in FIG. 14 and FIG. 16, in the embodiments of the present disclosure, before the conductive support layers 115 are formed, the extension portions 112 are first etched, that is, the horizontal width of the extension portions 112 is reduced, and the spacing between the extension portions 112 is increased. Then, the conductive film layer 113 is filled between the extension portions 112, and the conductive film layer 113 is further etched to form the conductive support layers 115. In the present disclosure, the extension portions 112 are first etched, and the etching gas may be blocked by the second sacrificial layer 105 to prevent the etching gas from etching the body portions 111, thereby protecting the body portions 111 and preventing interface damage on the body portions 111. Because only the extension portions 112 are etched, the etching gas does not need to be replaced in the etching process, and the etching process is relatively simple. In addition, when the conductive film layer 113 is etched, because the spacing between the extension portions 112 is increased, the conductive film layer 113 between the extension portions 112 can be more easily etched, thereby ensuring that the second sacrificial layer 105 between the extension portions 112 can be entirely exposed. Certainly, in some embodiments, when the bottom electrodes are formed, the extension portions 112 are not etched yet. Instead, after the conductive film layer 113 is formed, parts of the extension portions 112 are etched at the same time when the conductive film layer 113 is etched, thereby increasing the spacing between the extension portions 112. In this etching method, although the spacing between the extension portions 112 can be increased, a hole may be formed in the conductive film layer 113 during forming of the conductive film layer 113, as the spacing between the extension portions 112 is relatively small. Consequently, the supporting effect of the conductive support layers 115 is deteriorated. In addition, as the conductive film layer 113, the dielectric layer 114, and the extension portions 112 need to be etched at the same time, the etching gas needs to be replaced in the etching process, which makes the etching processes relatively complex. Therefore, before the conductive film layer 113 is formed, the extension portions 112 are etched to reduce the horizontal width of the extension portions 112 in the embodiments of the present disclosure.

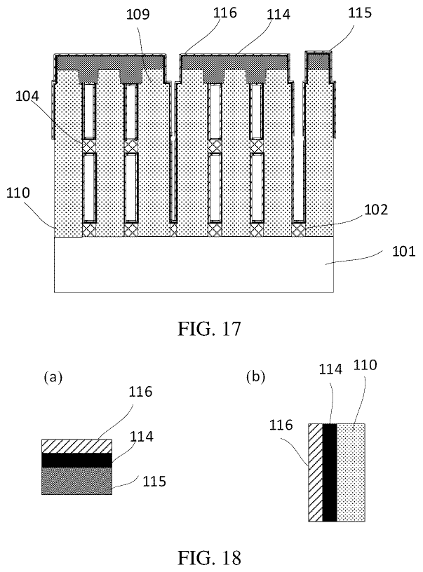

As shown in FIG. 17 and FIG. 18, in the step of S7, after the body portions 111 are exposed, a dielectric layer 114 is first formed on surfaces of the body portions 111, and the dielectric layer 114 may be located on the conductive support layers 115, and be further located on the intermediate support layer 104. After the dielectric layer 114 is formed, a top electrode 116 is formed on the dielectric layer 114, and the entire dielectric layer 114 can be covered by the top electrode 116. (a) in FIG. 18 is a positional relationship diagram for the conductive support layer 115, the dielectric layer 114, and the top electrode 116, and (b) in FIG. 18 is a positional relationship diagram for the body portion 110, the dielectric layer 114, and the top electrode 116. It can be seen from FIG. 18 that the dielectric layer 114 is located between the conductive support layer 115 and the top electrode 116. The dielectric layer 114 is located between the body portion 110 and the top electrode 116. The body portion 110, the dielectric layer 114, and the top electrode 116 may form a capacitor structure. The conductive support layer 115, the dielectric layer 114, and the top electrode 116 may also form a capacitor structure, thereby increasing a capacitor capacity.

As shown in FIG. 17 and FIG. 18, in the embodiments of the present disclosure, the dielectric layer 114 is formed on the body portions 111 by a chemical vapor deposition process, a physical vapor deposition process, or an atomic layer deposition process. Because the extension portions 112 are etched, the horizontal width of the extension portions 112 is reduced, and the spacing between the extension portions 112 is increased, deposited atoms can more easily enter a region between the extension portions 112 during deposition of the dielectric layer 114, and further the dielectric layer 114 is more easily formed on the body portions 111. For example, in the embodiments, as the spacing between the first bottom electrodes 109 is small and the height of the first bottom electrodes 109 is relatively large, the horizontal width of the extension portions 112 of the first bottom electrodes 109 is reduced, so that deposited atoms can more easily enter a region between the extension portions 112 of the first bottom electrodes 109, thereby more easily entering a region between the body portions 111 of the first bottom electrodes 109, and more easily forming the dielectric layer 114 on the first bottom electrodes 109. On the contrary, if the horizontal width of the extension portions 112 is not reduced, as the spacing between the first bottom electrodes 109 is small and the first bottom electrodes 109 are relatively high, the dielectric layer 114 cannot be easily formed on the first bottom electrodes 109, and further a capacitor structure cannot be formed. After the dielectric layer 114 is formed, the spacing between the first bottom electrodes 109 becomes smaller. By reducing the horizontal width of the extension portions 112 on the first bottom electrodes 109, the spacing between the extension portions 112 is increased, so that deposited atoms can more easily enter between the first bottom electrodes 109, thereby forming the top electrode 116 on the dielectric layer 114. Certainly, because the spacing between the second bottom electrodes 110 is relatively large, and the extension portions 112 on the second bottom electrodes 110 are also etched, the dielectric layer 114 and the top electrode 116 are more easily formed on the second bottom electrodes 110. As the sidewalls of the conductive support layers 115 are flush with the sidewalls of the extension portions 112, that is, there is no conductive support layer 115 between the extension portions 112 of adjacent ones of the first bottom electrodes 109, the conductive support layer 115 does not occupy a region between the extension portions 112 of the adjacent ones of the first bottom electrodes 109, thereby facilitating deposition of the dielectric layer 114 and the top electrode 116.

As shown in FIG. 18, in the embodiments of the present disclosure, the material of the dielectric layer 114 may be a high-K material, e.g., zirconium oxide, hafnium oxide, titanium zirconium oxide, ruthenium oxide, antimony oxide, or aluminium oxide. The material of the top electrode 116 may be metal nitride and metal silicide, e.g., titanium nitride and titanium silicon nitride.

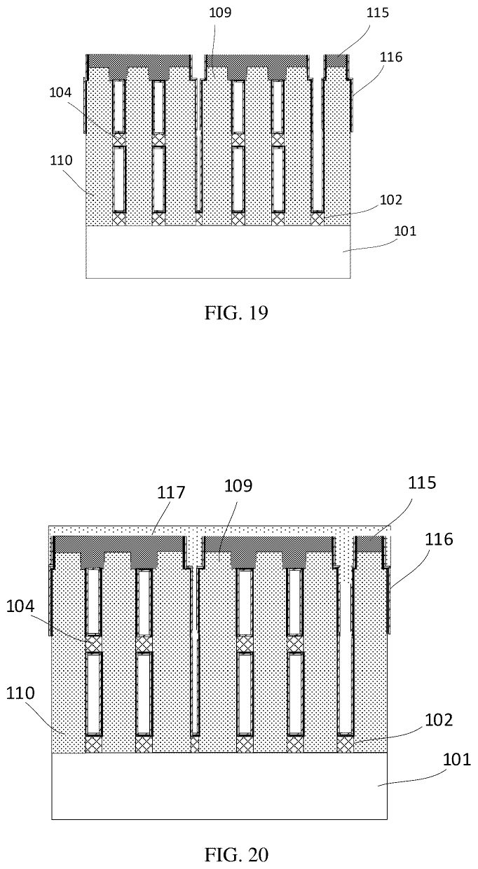

As shown in FIG. 19 and FIG. 20, in the embodiments of the present disclosure, the conductive support layers 115 are located on top of the second bottom electrodes 110, that is, the extension portions 112 of the second bottom electrodes 110 are covered by the conductive support layers 115. Certainly, the extension portions 112 of the first bottom electrodes 109 are also covered by the conductive support layers 115. As the conductive support layers 115 can support the first bottom electrodes 109 and the second bottom electrodes 110, and the conductive support layers 115 are conductive, the conductive support layers 115 may act as wires, that is, interconnection with a metal pillar can be implemented through the conductive support layers 115, thereby implementing signal transmission. Certainly, in some embodiments, after the top electrode 116 is formed, the dielectric layer 114 and the top electrode 116 that are located on upper surfaces of the conductive support layers 115 may be further removed, that is, the dielectric layer 114 and the top electrode 116 that are located on the sidewalls of the conductive support layers 115 are exposed. In other words, the top electrode 116 may extend from the first bottom electrodes 109 or the second bottom electrodes 110 to the conductive support layers 115, so that the conductive support layers 115 and the top electrode 116 are coplanar with each other, and then a top electrode plate 117 is formed on the conductive support layers 115, and the conductive support layers 115 may be covered by the top electrode plate 117. A part of the top electrode plate 117 may be further located in a region between adjacent ones of the conductive support layers 115, and extend between the body portions 111, so that the top electrode plate 117 is interconnected with the top electrode 116 between the body portions 111 and the top electrode 116 on the conductive support layers 115, thereby increasing a contact area between the top electrode plate 117 and the top electrode 116, reducing contact resistance, and further providing a support function. The material of the top electrode plate 117 may be the same as the material of the conductive support layers 115, and the top electrode plate 117 and the top electrode 116 may be of an integrated structure, thereby jointly supporting the bottom electrodes, and also providing a conduction function.

In some embodiments, the top electrode plate 117 may be further filled only in a region between the conductive support layers 115 and extend between the first bottom electrodes 109 to provide a support function, so that a metal pillar can be directly formed on the conductive support layers 115. The conductive support layers 115 may support the first bottom electrodes 109, and may also be configured for conduction. In addition, the height of the capacitor structure may be further reduced to relieve pressure of the top electrode plate 117 on the first bottom electrodes 109 and the second bottom electrodes 110, thereby alleviating a risk of collapse of the first bottom electrodes 109 and the second bottom electrodes 110.

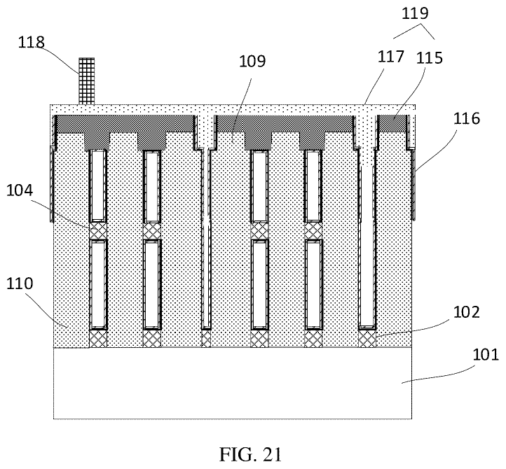

As shown in FIG. 21, embodiments of the present disclosure further propose a semiconductor structure. The semiconductor structure may include a base 101. Multiple first bottom electrodes 109 and multiple second bottom electrodes 110 are present on the base 101. The first bottom electrodes 109 and the second bottom electrodes 110 may be collectively referred to as bottom electrodes. A bottom support layer 102 is provided at the bottom of each of the first bottom electrodes 109, an intermediate support layer 104 is provided in a middle region of each of the first bottom electrodes 109, first conductive support layers 115 are provided at the top of the first bottom electrodes 109, and a second conductive support layer 117 is provided on the first conductive support layers 115. The first conductive support layers 115 and the second conductive support layer 117 jointly form a conductive support layer 119. The bottom support layer 102 and the intermediate support layer 104 each are an insulating material, e.g., silicon nitride. The first conductive support layers 115 are germanium silicon, and the second conductive support layer 117 is germanium silicon. Both of the conductive support layers have the same material, thereby reducing interface resistance. A dielectric layer is present between the first conductive support layers 115 and the first bottom electrodes 109, and a dielectric layer is present between the first conductive support layers 115 and the second bottom electrodes 110. Therefore, the first conductive support layers 115 can support the first bottom electrodes 109 and the second bottom electrodes 110. In addition, a metal pillar 118 is provided on the second conductive support layer 117, and a signal can be transmitted to the first conductive support layers 115 through the metal pillar 118 and be further transmitted to a capacitor structure. Therefore, the first conductive support layers 115 and the second conductive support layer 117 can further provide a conduction function.

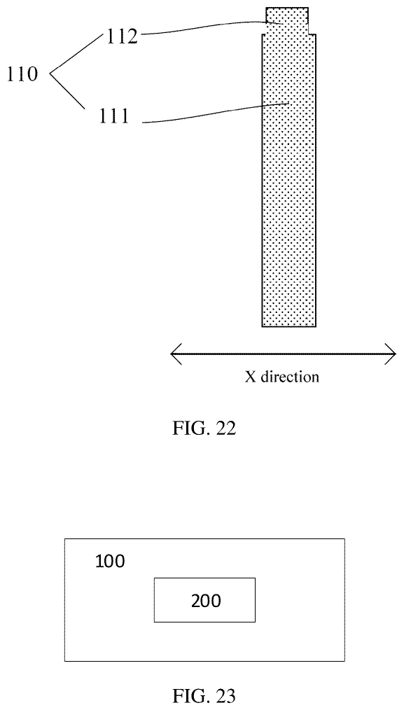

As shown in FIG. 21 and FIG. 22, the present disclosure is described by taking the second bottom electrodes 110 as an example. Each of the second bottom electrodes 110 may include a body portion 111 and an extension portion 112. The extension portion 112 is located above the body portion 111, and in the X direction (horizontal direction), the horizontal width of the extension portion 112 is less than the horizontal width of the body portion 111. Therefore, a spacing between the extension portions 112 may be greater than a spacing between the body portions 111. In addition, the first conductive support layers 115 may be further located on the extension portions 112, that is, the extension portions 112 are covered by the first conductive support layers 115, and sidewalls of the first conductive support layers 115 are flush with sidewalls of the extension portions 112. In addition, a top electrode 116 is further provided on sidewalls of all of the first bottom electrodes 109, the second bottom electrodes 110, and the extension portions 112, as well as the sidewalls of the first conductive support layers 115. The first conductive support layers 115 are covered by the second conductive support layer 117, and a part of the second conductive support layer 117 is further located between the first conductive support layers 115 and between the extension portions 112, so as to extend between the body portions 111 and further come into contact with the top electrode 116 on the first conductive support layers 115, the extension portions 112, and the body portions 111, thereby increasing a contact area and reducing contact resistance. In addition, the second conductive support layer 117 extends between the body portions 111, and therefore can support the first bottom electrodes 109 and the second bottom electrodes 110.

As shown in FIG. 21 and FIG. 22, in the embodiments of the present disclosure, the height of the extension portions 112 is substantially the same as the thickness of the intermediate support layer 104. Therefore, it can be ensured that the body portions 110 have a proper height to ensure a capacitor capacity. The overall height of the capacitor structure can be further reduced to alleviate a risk of collapse of the bottom electrodes. In the embodiments, the extension portions 112 are covered by the conductive support layer 119. Therefore, the thickness of the conductive support layer 119 is greater than the thickness of the intermediate support layer 104. Therefore, the thickness of the conductive support layer 119 can be increased to improve a support function and also reduce resistance of the conductive support layer 119.

As shown in FIG. 21, a dielectric layer 114 is further present between the top electrode 116 and the first bottom electrodes 109 (referring to FIG. 18), and a dielectric layer 114 is further present between the first conductive support layers 115 and the extension portions 112 (referring to FIG. 18). The top electrode 116, the first bottom electrode 109, and the dielectric layer 114 may jointly form a capacitor structure, and the first conductive support layer 115, the extension portion 112, and the dielectric layer 114 may further jointly form a capacitor structure, thereby increasing a capacitor capacity.

It should be noted that, for a manufacturing method for the semiconductor structure in FIG. 21, reference may be made to the foregoing descriptions.

As shown in FIG. 23, embodiments of the present disclosure further propose an electronic device 100. The electronic device 100 may include a semiconductor structure 200. For the semiconductor structure 200, reference may be made to the structure in FIG. 21. For a manufacturing method for the semiconductor structure 200, reference may be made to the foregoing descriptions. The electronic device 100 may include one or more of the following: e.g., a smart phone, a tablet personal computer (PC), a mobile phone, a video phone, an e-book (e-book) reader, a desktop PC, a laptop PC, a netbook computer, a workstation, a server, a personal digital assistant (PDA), a portable multimedia player (PMP), an MPEG-1 audio layer 3 (MP3) player, a mobile medical device, a camera, a home appliance, a medical device, an Internet of Things (IoT) device, and a wearable device. The wearable device may be of an accessory type, a fabric or clothing type, a body attachment type, or an implantable circuit type. An accessory-type wearable device may be, e.g., a watch, a ring, a bracelet, an anklet, a necklace, glasses, contact lenses, or a head-mounted device (HMD).

In conclusion, the embodiments of the present disclosure propose the semiconductor structure and the manufacturing method therefor. After the second sacrificial layer is formed on the base, the mask layer is directly formed on the second sacrificial layer. That is, after the stack without the top support layer (silicon nitride) is formed, no lateral etching is performed on the second sacrificial layer by the etching gas during etching of the stack. Therefore, it can be ensured that the bottom electrodes are not interconnected, and in a subsequent process, the first sacrificial layer and the second sacrificial layer can be entirely cleaned up to avoid residuals of the first sacrificial layer, thereby facilitating formation of a capacitor.

In addition, as the capacitor holes have a high depth-to-width ratio and a high density, the aperture of some capacitor holes is increased, and the diameter of the first bottom electrodes is accordingly increased, resulting in a relatively small spacing between the first bottom electrodes. Therefore, by reducing the horizontal width of the extension portions and increasing the spacing between the extension portions, the spacing between the extension portions is made greater than the spacing between the body portions. In this way, deposited atoms can more easily enter between the body portions, thereby facilitating formation of the dielectric layer and the top electrode, ensuring formation of a capacitor structure, and simplifying a technological process.

Further, as the conductive support layers are located on the extension portions, the bottom electrodes can be supported by the conductive support layers. In addition, the conductive support layers may be further configured for the top electrode plate, that is, configured for power transmission. Because the dielectric layer is present between the conductive support layers and the extension portions, a capacitor structure can be formed, thereby increasing a capacitor capacity.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A manufacturing method for a semiconductor structure, comprising:
forming a stack on a base;
forming a plurality of bottom electrodes in the stack, each of the bottom electrodes comprising a body portion in the stack and an extension portion protruding from the stack;
etching the extension portion, so that a horizontal width of the extension portion is less than a horizontal width of the body portion;
successively forming a dielectric layer and a conductive film layer on the stack, the extension portion being covered by the dielectric layer and the conductive film layer;
etching the conductive film layer to expose the stack and form a plurality of conductive support layers;
etching the stack to expose the body portion;
forming a dielectric layer on the body portion; and
forming a top electrode on the dielectric layer.

2. The manufacturing method according to claim 1, wherein the step of forming the stack comprises the following:
forming a bottom support layer on the base;
forming a first sacrificial layer on the bottom support layer;
forming an intermediate support layer on the first sacrificial layer; and
forming a second sacrificial layer on the intermediate support layer.

3. The manufacturing method according to claim 2, wherein the step of forming the bottom electrodes comprises the following:
forming a mask layer on the second sacrificial layer;
etching the stack based on the mask layer to form capacitor holes in the stack;
forming the bottom electrodes in the capacitor holes; and
removing a part of the second sacrificial layer, so that the bottom electrodes protrude from the stack.

4. The manufacturing method according to claim 3, wherein the step of removing a part of the second sacrificial layer comprises the following:
removing a part of the second sacrificial layer through dry etching to form the extension portion;
a height of the extension portion being substantially the same as a thickness of the intermediate support layer.

5. The manufacturing method according to claim 3, wherein the capacitor holes are filled with a bottom-electrode material to form the plurality of bottom electrodes; and the bottom electrodes comprise the following:
a plurality of first bottom electrodes; and
a plurality of second bottom electrodes;
a spacing between adjacent ones of the first bottom electrodes being less than a spacing between adjacent ones of the second bottom electrodes.

6. The manufacturing method according to claim 1, wherein the step of forming the conductive support layers comprises the following:
removing the conductive film layer between the extension portions to expose the dielectric layer on sidewalls of the extension portions and expose the stack; and
removing the dielectric layer on the sidewalls of the extension portions to expose the sidewalls of the extension portions.

7. The manufacturing method according to claim 6, wherein the step of forming the conductive support layers comprises the following: removing a part of the conductive film layer between adjacent ones of the first bottom electrodes to expose the second sacrificial layer between the adjacent ones of the first bottom electrodes.

8. The manufacturing method according to claim 1, wherein the step of forming the top electrode comprises the following:
depositing a top-electrode material on the dielectric layer, the top-electrode material being further located on the conductive support layers;
the dielectric layer being present between the top-electrode material and the conductive support layers.

9. The manufacturing method according to claim 1, further comprising: forming a top electrode plate on the conductive support layers, the top electrode plate coming into contact with the top electrode located on the conductive support layers.

10. The manufacturing method according to claim 9, wherein the top electrode plate further extends between adjacent ones of the body portions to come into contact with the top electrode between the body portions.

11. A semiconductor structure, comprising:
a base;
a plurality of bottom electrodes located on the base, each of the bottom electrodes comprising a body portion and an extension portion, and a horizontal width of the extension portion being less than a horizontal width of the body portion;
an intermediate support layer, located in a middle region of the body portion;
a conductive support layer, located on the extension portion, a dielectric layer being present between the conductive support layer and the extension portion; and
a conductive pillar, located on the conductive support layer.

12. The semiconductor structure according to claim 11, wherein the dielectric layer is further located on the body portion, and a top electrode is further disposed on the dielectric layer.

13. The semiconductor structure according to claim 11, wherein the conductive support layer extends between the bottom electrodes and comes into contact with the top electrode located between the bottom electrodes.

14. The semiconductor structure according to claim 11, wherein the conductive support layer protrudes from the top electrode.

15. The semiconductor structure according to claim 11, wherein a thickness of the conductive support layer is greater than a thickness of the intermediate support layer.
